(19) United States
(12) Patent Application Publication
(10) Pub. No.: US 2016/0079003 A1
(43) Pub. Date: Mar. 17, 2016

(54) METHOD OF CONTROLLING MEMS VARIABLE CAPACITOR AND INTEGRATED CIRCUIT DEVICE

(71) Applicant: Kabushiki Kaisha Toshiba, Tokyo (JP)

(72) Inventors: Tsuyoshi Hirayu, Yokohama Kanagawa (JP); Tamio Ikehashi, Yokohama Kanagawa (JP)

(21) Appl. No.: 14/645,256

(22) Filed: Mar. 11, 2015

(30) Foreign Application Priority Data
Sep. 12, 2014 (JP) 2014-186249

(51) Int. Cl. H01G 5/16; B81B 3/00

(52) U.S. Cl. CPC H01G 5/16; B81B 3/0059

(57) ABSTRACT

According to one embodiment, a method of controlling a MEMS variable capacitor includes first and second electrodes, and having a capacitance varying according to a voltage applied between the first and second electrodes, the method includes applying a voltage between the first and second electrodes, evaluating whether the capacitance of the MEMS variable capacitor satisfies a predetermined condition while the voltage is being applied between the first and second electrodes, and determining that the voltage applied between the first and second electrodes is a voltage which should be applied therebetween, on a condition that the capacitance of the MEMS variable capacitor is evaluated as satisfying the predetermined condition.

### CROSS-REFERENCE TO RELATED APPLICATIONS

This application is based upon and claims the benefit of priority from Japanese Patent Application No. 2014-186249, filed Sep. 12, 2014, the entire contents of which are incorporated herein by reference.

### FIELD

Embodiments described herein relate generally to a method of controlling a MEMS variable capacitor and an integrated circuit device.

### BACKGROUND

Electronic devices in which a variable capacitor which uses micro-electro-mechanical systems (MEMS) technology is formed on a semiconductor substrate are proposed. This variable capacitor (MEMS variable capacitor) has a feature that the distance between electrodes changes according to the voltage applied between the electrodes, thereby varying its capacitance. More specifically, the capacitor can set two states, namely, a state in which the distance between electrodes is relatively great (an up state) and a state in which the distance between electrodes is relatively small (a down state).

The above-described MEMS variable capacitor is formed using a movable electrode, its capacitance deviates from a desired one in some cases. Under these circumstances, there is a demand for a control method for a MEMS variable capacitor, which can reliably obtain a desired capacitance, and also an integrated circuit device comprising such a MEMS variable capacitor.

### BRIEF DESCRIPTION OF THE DRAWINGS

FIG. 1 is a block diagram showing a device structure of a first embodiment;

FIG. 2 is a diagram schematically showing a structure of a MEMS variable capacitor according to the first embodiment;

FIG. 3 is a diagram schematically showing a structure of a MEMS variable capacitor according to the first embodiment;

FIG. 4 is a flowchart showing an operation of the first embodiment; and

FIG. 5 is a block diagram showing a device structure of a second embodiment.

### DETAILED DESCRIPTION

In general, according to one embodiment, a method of controlling a MEMS variable capacitor comprising first and second electrodes, and having a capacitance varying according to a voltage applied between the first and second electrodes, the method includes: applying a voltage between the first and second electrodes; evaluating whether the capacitance of the MEMS variable capacitor satisfies a predetermined condition while the voltage is being applied between the first and second electrodes; and determining that the voltage applied between the first and second electrodes is a voltage which should be applied therebetween, on a condition that the capacitance of the MEMS variable capacitor is evaluated as satisfying the predetermined condition.

Embodiments will now be described with reference to drawings.

(Embodiment 1)

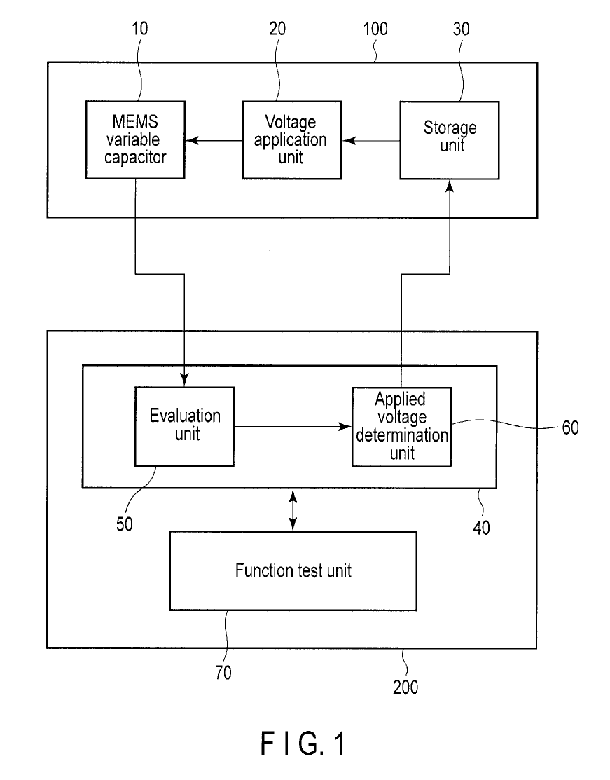

FIG. 1 is a block diagram showing a device structure of the first embodiment. The device shown in FIG. 1 comprises an integrated circuit device (semiconductor integrated circuit device) 100 comprising a MEMS variable capacitor, a transistor and the like, and a test device 200 configured to test and control the integrated circuit device 100. The test device 200 is provided outside the MEMS variable capacitor, and data are transmitted between the integrated circuit device 100 and the test device 200.

The integrated circuit device 100 comprises a MEMS variable capacitor 10, a voltage application unit 20 and a storage unit 30.

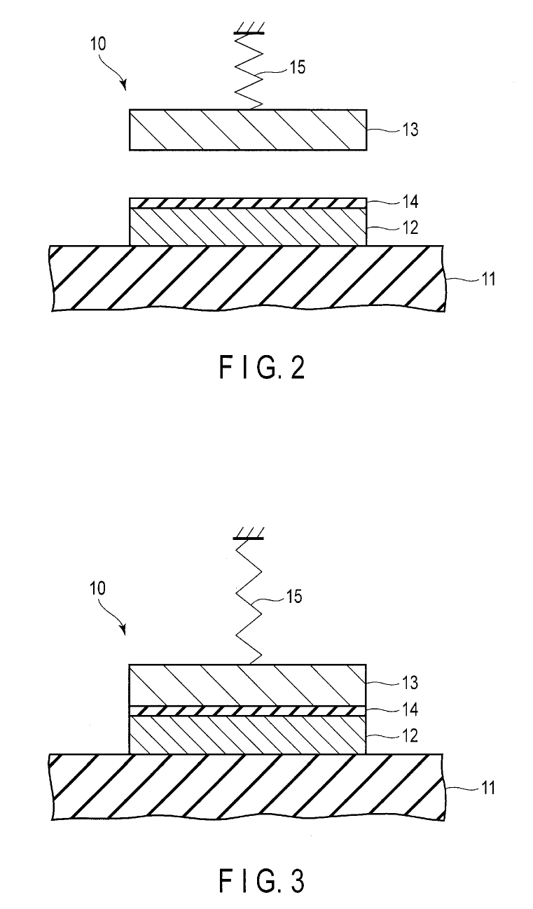

FIGS. 2 and 3 each are a diagram schematically showing a structure of the MEMS variable capacitor 10.

As shown in FIGS. 2 and 3, the MEMS variable capacitor 10 is formed on an underlying region 11 which includes a semiconductor substrate, a transistor and an interlayer insulating film, and the like. The MEMS variable capacitor 10 comprises a fixed lower electrode (first electrode) 12, a movable upper electrode (second electrode) 13 and an insulating film 14 located between the lower electrode 12 and the upper electrode 13. The upper electrode 13 is supported by a spring 15. The MEMS variable capacitor 10 is formed with the MEMS technology.

FIG. 2 shows a first state (up state) in which the distance between the fixed lower electrode (first electrode) 12 and the movable upper electrode (second electrode) 13 is a first distance. FIG. 3 shows a second state (down state) in which the distance between the fixed lower electrode (first electrode) 12 and the movable upper electrode (second electrode) 13 is a second distance which is less than the first distance.

The MEMS variable capacitor 10 changes its capacitance according to the distance (gap width) between the lower electrode 12 and the upper electrode 13. For example, when a voltage is applied between the lower electrode 12 and the upper electrode 13, an electrostatic force acts between the lower electrode 12 and the upper electrode 13 and thus changes the distance (gap width) between the lower electrode 12 and the upper electrode 13 according to the voltage applied between the lower electrode 12 and the upper electrode 13. The MEMS variable capacitor 10 of this embodiment shifts from the up state to the down state as a result of application of a voltage higher than or equal to a predetermined threshold voltage between the lower electrode 12 and the upper electrode 13.

To the MEMS variable capacitor 10, the voltage application unit 20 is connected to apply a voltage between the electrodes of the MEMS variable capacitor 10. With this structure, the MEMS variable capacitor 10 can be set to the up state or down state by controlling the voltage applied between the electrodes with the voltage application unit 20. The voltage application unit 20 comprises a booster circuit to produce an applied voltage, or the like.

To the voltage application unit 20, the storage unit 30 is connected, and based on the applied voltage data stored in the storage unit 30, a voltage to be applied from the voltage application unit 20 to the MEMS variable capacitor 10 is produced.

The test device 200 comprises a control unit 40 and a function test unit 70. The control unit 40 comprises an evaluation unit 50 and an applied voltage determination unit 60.

The evaluation unit 50 is configured to measure the capacitance of the MEMS variable capacitor 10 while an evaluation voltage (DC voltage) is being applied between the lower electrode 12 and the upper electrode 13. The evaluation unit 50 is configured to evaluate whether or not the capacitance of the MEMS variable capacitor 10 is satisfying a predetermined condition. More specifically, the evaluation unit 50 is configured to evaluate whether or not the capacitance of the MEMS variable capacitor 10 is satisfying a predetermined condition when the MEMS variable capacitor 10 is in the down state.

In this embodiment, the evaluation as to whether or not the capacitance of the MEMS variable capacitor 10 is satisfying a predetermined condition includes an evaluation as to whether or not the capacitance of the MEMS variable capacitor 10 is within a predetermined range while the evaluation voltage is being applied between the lower electrode 12 and the upper electrode 13. This point will now be described in detail.

As already described, the MEMS variable capacitor 10 shifts from the up state to the down state when a voltage higher than or equal to a predetermined threshold voltage is applied between the lower electrode 12 and the upper electrode 13. However, if, for example, the upper electrode 13 is curved, the capacitance in the down state varies in some cases. When the capacitance varies, the capacitance in the down state deviates from a desired one (a target capacitance).

At this point, the evaluation unit 50 evaluates whether or not the capacitance in the down state falls within a predetermined range. That is, whether or not the capacitance in the down state falls within a predetermined error range with regard to the target capacitance is determined. For example, when the tolerable minimum capacitance is Cmin and the tolerable maximum capacitance is Cmax, it is determined as to whether or not the detected capacitance is between Cmin and Cmax.

To the evaluation unit 50, the applied voltage determination unit 60 is connected. The applied voltage determination unit 60 is configured to determine, when the capacitance of the MEMS variable capacitor 10 is evaluated as satisfying the above-described predetermined condition, that the voltage for evaluation applied between the lower electrode 12 and the upper electrode 13 is the one that should be applied between the lower electrode 12 and the upper electrode 13. The applied voltage determination unit 60 is configured to adjust the voltage applied between the lower electrode 12 and the upper electrode 13 to satisfy the above-described predetermined condition until the capacitance of the MEMS variable capacitor 10 is evaluated to satisfy the above-described predetermined condition. More specifically, when the detected capacitance is not between Cmin and Cmax, the voltage applied between the lower electrode 12 and the upper electrode 13 is adjusted so as to set the capacitance between Cmin and Cmax. When the voltage applied between the lower electrode 12 and the upper electrode 13 is adjusted, the distance between the lower electrode 12 and the upper electrode 13 is adjusted, thereby making it possible to adjust the capacitance.

The voltage (value) determined in the applied voltage determination unit 60 is transmitted to the storage unit 30. The storage unit 30 stores data on the voltage determined.

When the device (the integrated circuit device 100) in which the MEMS variable capacitor 10 is incorporated is actually used, the voltage data stored in the storage unit 30 is read out. The read voltage data is transferred to the voltage application unit 20, and the voltage generated by the voltage application unit 20 is applied between the electrodes of the MEMS variable capacitor 10. The voltage applied to the MEMS variable capacitor 10 is adjusted such that the capacitance of the MEMS variable capacitor 10 satisfies the predetermined condition, an appropriate voltage is applied to the MEMS variable capacitor 10.

To the control unit 40 of the test device 200, the function test unit 70 is connected. With the function test unit 70, various tests can be carried out on the integrated circuit device 100 including the MEMS variable capacitor 10.

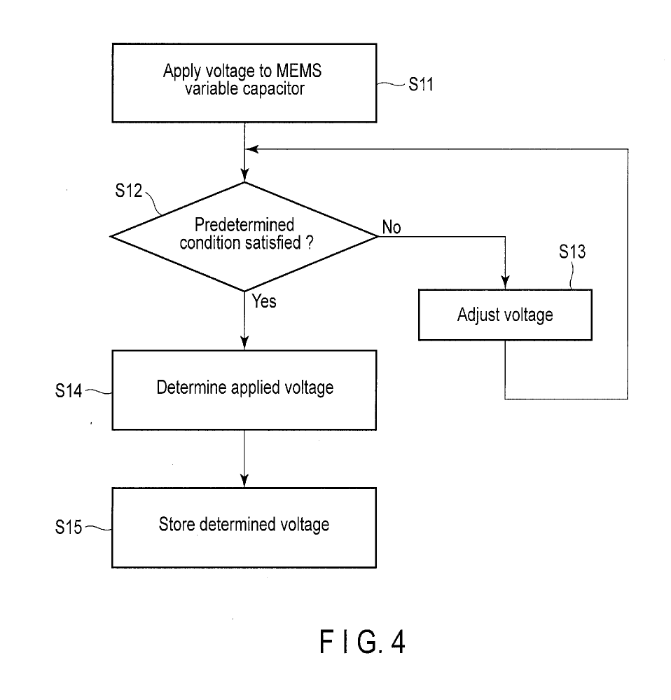

Next, the operation of this embodiment will be described. FIG. 4 is a flowchart showing the operation of this embodiment. It should be noted that the operation of this embodiment is executed based on a program stored in the control unit 40, and further, the operation of this embodiment can be carried out when the integrated circuit device 100 is subjected to a die sort.

First, a voltage (evaluation voltage) generated by the voltage application unit 20 is applied between the lower electrode 12 and the upper electrode 13 of the MEMS variable capacitor 10 (step S11).

While the voltage is being applied between the lower electrode 12 and the upper electrode 13, the evaluation unit 50 determines whether or not the capacitance of the MEMS variable capacitor 10 satisfies the predetermined condition (step S12). That is, it is determined whether or not the capacitance of the MEMS variable capacitor 10 falls within a predetermined range when the MEMS variable capacitor 10 is in the down state. More specifically, when the tolerable minimum capacitance is Cmin and the tolerable maximum capacitance is Cmax, it is determined whether or not the detected capacitance is between Cmin and Cmax.

In step S12, if the capacitance of the MEMS variable capacitor 10 does not satisfy the predetermined condition, the voltage applied to the MEMS variable capacitor 10 is adjusted (varied) based on the evaluation results (step S13). For example, when the detected capacitance is less than Cmin, the applied voltage is increased to reduce the inter-electrode distance. On the other hand, when the detected capacitance is greater than Cmax, the applied voltage is decreased to increase the inter-electrode distance.

After the applied voltage is adjusted, the procedure returns to step S12, where it is once again evaluated as to whether or not the capacitance of the MEMS variable capacitor 10 satisfies the predetermined condition.

If it is determined in step S12 that the capacitance of the MEMS variable capacitor 10 satisfies the predetermined condition, the voltage for evaluation applied between the lower electrode 12 and the upper electrode 13 is determined as the one that should be applied between the lower electrode 12 and the upper electrode 13 for actual use (step S14).

The voltage data determined in step S14 is transmitted to the storage unit 30, where the voltage data is stored (step S15).

When the device (the integrated circuit device 100) in which the MEMS variable capacitor 10 is incorporated is actually used, the voltage data stored in the storage unit 30 is read out. The read voltage data is transferred to the voltage application unit 20, and the voltage generated by the voltage application unit 20 is applied between the electrodes of the MEMS variable capacitor 10. In this manner, an appropriate capacitance can be set to the MEMS variable capacitor 10.

As described above, according to this embodiment, it is determined whether or not the capacitance of the MEMS variable capacitor 10 satisfies the predetermined condition while the evaluation voltage is being applied between the electrodes of the MEMS variable capacitor 10. When it is evaluated as satisfying the predetermined condition, the evaluation voltage is determined as the one that should be applied between the electrodes. In this manner, the capacitance of the MEMS variable capacitor 10 can be set to a desired appropriate capacitance. As a result, when the device (the integrated circuit device 100) in which the MEMS variable capacitor 10 is incorporated is actually used, an appropriate operation can be assured.

Thus, even in the case where the capacitance in the down state varies because of, for example, curvature of the upper electrode 13, an appropriate capacitance can be obtained by applying an appropriate voltage between the electrodes.

Further, an appropriate applied voltage can be effectively determined by adjusting the applied voltage based on the evaluation results.

Moreover, in this embodiment, since the control unit 40 (the evaluation unit 50 and the applied voltage determination unit 60) is included in the test device 200, the structure of the integrated circuit device 100 can be simplified.

(Embodiment 2)

Next, the second embodiment will now be described. Note that the basis structure and basic operation are similar to those of the first embodiment. Therefore, the description of the items already made in the first embodiment will be omitted.

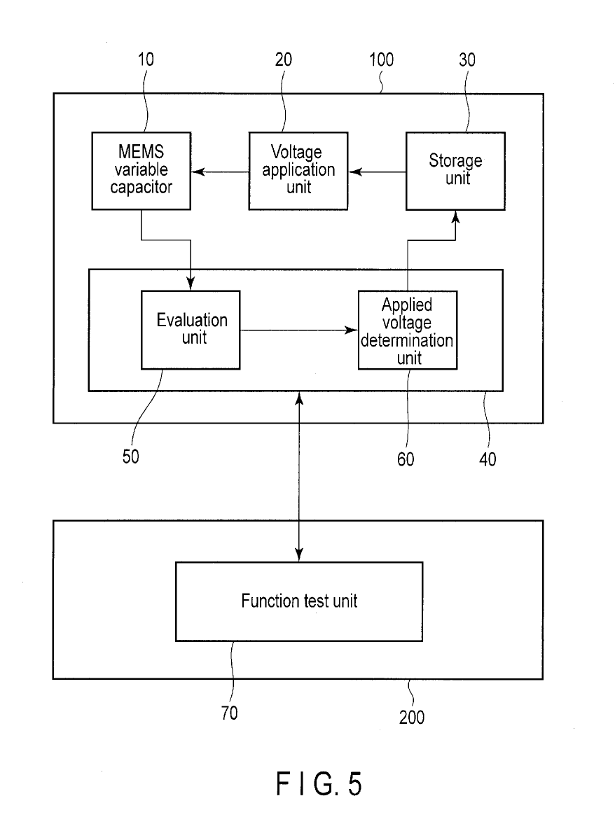

FIG. 5 is a block diagram showing a device structure of a second embodiment. In FIG. 5, the structural elements corresponding to those shown in FIG. 1 will be designated by the same reference numbers, and detailed descriptions therefore will be omitted.

As shown in FIG. 5, according to this embodiment, in addition to a MEMS variable capacitor 10, a voltage application unit 20 and a storage unit 30, a control unit 40 (an evaluation unit 50 and an applied voltage determination unit 60) is included in an integrated circuit device 100. Since the evaluation unit 50 is included in the integrated circuit device 100, a reference capacitor having a reference capacitance is provided in the integrated circuit device 100. With this structure, the capacitance of the MEMS variable capacitor 10 can be evaluated based on the reference capacitance.

This embodiment involves a basis structure and basic operation similar to those of the first embodiment, and therefore it can exhibit an advantageous effect similar to that of the first embodiment.

Further, in this embodiment, the control unit 40 (the evaluation unit 50 and the applied voltage determination unit 60) is included in an integrated circuit device 100, and with this structure, the capacitance of the MEMS variable capacitor 10 can be adjusted when a device (the integrated circuit device 100) in which the MEMS variable capacitor 10 is incorporated is actually used. Therefore, even in a case where the capacitance of the MEMS variable capacitor 10 varies when actual use, the varied capacitance can be adjusted to an appropriate one.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of controlling a MEMS variable capacitor comprising first and second electrodes, and having a capacitance varying according to a voltage applied between the first and second electrodes, the method comprising:
applying a voltage between the first and second electrodes;
evaluating whether the capacitance of the MEMS variable capacitor satisfies a predetermined condition while the voltage is being applied between the first and second electrodes; and
determining that the voltage applied between the first and second electrodes is a voltage which should be applied therebetween, on a condition that the capacitance of the MEMS variable capacitor is evaluated as satisfying the predetermined condition.

2. The method of controlling the MEMS variable capacitor of claim 1, wherein
the MEMS variable capacitor has a first state in which a distance between the first and second electrodes is a first distance and a second state in which the distance between the first and second electrodes is a second distance less than the first distance, and
the evaluating whether the capacitance of the MEMS variable capacitor satisfies the predetermined condition comprises evaluating whether the capacitance of the MEMS variable capacitor satisfies the predetermined condition while the MEMS variable capacitor is in the second state.

3. The method of controlling the MEMS variable capacitor of claim 1, wherein
the evaluating whether the capacitance of the MEMS variable capacitor satisfies the predetermined condition comprises evaluating whether the capacitance of the MEMS variable capacitor falls within a predetermined range while a voltage is being applied between the first and second electrodes.

4. The method of controlling the MEMS variable capacitor of claim 1, wherein
the determining that the voltage applied between the first and second electrodes is the voltage which should be applied therebetween comprises adjusting the voltage applied between the first and second electrodes to satisfy the predetermined condition until it is evaluated that the capacitance of the MEMS variable capacitor satisfies the predetermined condition.

5. The method of controlling the MEMS variable capacitor of claim 1, further comprising:
storing the voltage determined.

6. The method of controlling the MEMS variable capacitor of claim 1, wherein
the MEMS variable capacitor is provided in an integrated circuit device.

7. The method of controlling the MEMS variable capacitor of claim 6, wherein
the evaluating whether the capacitance of the MEMS variable capacitor satisfies the predetermined condition is carried out outside the integrated circuit device.

8. The method of controlling the MEMS variable capacitor of claim 6, wherein
the evaluating whether the capacitance of the MEMS variable capacitor satisfies the predetermined condition is carried out in the integrated circuit device.

9. The method of controlling the MEMS variable capacitor of claim 6, wherein
the determining that the voltage applied between the first and second electrodes is the voltage which should be applied therebetween is carried out outside the integrated circuit device.

10. The method of controlling the MEMS variable capacitor of claim 6, wherein
the determining that the voltage applied between the first and second electrodes is the voltage which should be applied therebetween is carried out in the integrated circuit device.

11. An integrated circuit device comprising:
a MEMS variable capacitor comprising first and second electrodes, and having a capacitance varying according to a voltage applied between the first and second electrodes;
a voltage application unit applying a voltage between the first and second electrodes;
an evaluation unit evaluating whether the capacitance of the MEMS variable capacitor satisfies a predetermined condition while the voltage is being applied between the first and second electrodes; and
an applied voltage determination unit determining that the voltage applied between the first and second electrodes is a voltage which should be applied therebetween, on a condition that the capacitance of the MEMS variable capacitor is evaluated as satisfying the predetermined condition.

12. The integrated circuit device of claim 11, wherein
the MEMS variable capacitor has a first state in which a distance between the first and second electrodes is a first distance and a second state in which the distance between the first and second electrodes is a second distance less than the first distance, and
the evaluation unit is configured to evaluate whether the capacitance of the MEMS variable capacitor satisfies the predetermined condition while the MEMS variable capacitor is in the second state.

13. The integrated circuit device of claim 11, wherein
the evaluation unit is configured to evaluate whether the capacitance of the MEMS variable capacitor falls within a predetermined range while a voltage is being applied between the first and second electrodes.

14. The integrated circuit device of claim 11, wherein
the applied voltage determination unit is configured to adjust the voltage applied between the first and second electrodes to satisfy the predetermined condition until it is evaluated that the capacitance of the MEMS variable capacitor satisfies the predetermined condition.

15. The integrated circuit device of claim 11, further comprising:
a storage unit storing the voltage determined.

16. A method of controlling a MEMS variable capacitor comprising first and second electrodes, and having a capacitance varying according to a voltage applied between the first and second electrodes, the method comprising:
applying a voltage between the first and second electrodes;
measuring the capacitance of the MEMS variable capacitor while the voltage is being applied between the first and second electrodes; and
applying the voltage between the first and second electrodes, on a condition that the capacitance of the MEMS variable capacitor is satisfying a predetermined condition.

17. The method of controlling the MEMS variable capacitor of claim 16, further comprising:
adjusting the voltage applied between the first and second electrodes to satisfy the predetermined condition.

18. The method of controlling the MEMS variable capacitor of claim 17, wherein
the adjusted voltage is applied between the first and second electrodes.

19. The method of controlling the MEMS variable capacitor of claim 17, wherein
adjusting the voltage includes varying a distance between the first and second electrodes.

20. The method of controlling the MEMS variable capacitor of claim 16, wherein
the MEMS variable capacitor has a first state in which a distance between the first and second electrodes is a first distance and a second state in which the distance between the first and second electrodes is a second distance less than the first distance, and
measuring the capacitance includes measuring the capacitance of the MEMS variable capacitor while the MEMS variable capacitor is in the second state.
